(19) United States
(12) Patent Application Publication
(10) Pub. No.: US 2023/0317363 A1
(43) Pub. Date: Oct. 5, 2023

(54) ELECTRONIC COMPONENT, ELECTRONIC COMPONENT MANUFACTURING METHOD, AND CIRCUIT MODULE

(71) Applicant: Murata Manufacturing Co., Ltd., Kyoto (JP)

(72) Inventor: Hirofumi OIE, Nagaokakyo-shi (JP)

(21) Appl. No.: 18/330,396

(22) Filed: Jun. 7, 2023

Related U.S. Application Data
(63) Continuation of application No. PCT/JP2021/047650, filed on Dec. 22, 2021.

(30) Foreign Application Priority Data
Dec. 25, 2020 (JP) 2020-217091

(51) Int. Cl. H01F 27/29; H01F 41/04

(52) U.S. Cl. CPC H01F 27/292; H01F 41/04

(57) ABSTRACT

To provide electronic component that can be easily designed for improving performance of electronic component by increasing a degree of freedom of arrangement of via conductor and internal electrode inside electronic component, method for manufacturing electronic component, and circuit module. Electronic component according to the present disclosure includes element body having outer surface, via conductor configured to penetrate at least a part of element body in a thickness direction of element body, via conductor provided so that one end surface is flush with outer surface of element body, and columnar electrode having base end portion electrically connected to one end surface of via conductor, so as to protrude in thickness direction from outer surface of element body. A length in thickness direction of columnar electrode is longer than maximum width in cross section orthogonal to thickness direction of columnar electrode.

### CROSS REFERENCE TO RELATED APPLICATION

This is a continuation of International Application No. PCT/JP2021/047650 filed on Dec. 22, 2021 which claims priority from Japanese Patent Application No. 2020-217091 filed on Dec. 25, 2020. The contents of these applications are incorporated herein by reference in their entireties.

### BACKGROUND OF THE DISCLOSURE

### Field of the Disclosure

The present disclosure relates to an electronic component including an external electrode and a method for manufacturing the same.

### Description of the Related Art

Conventionally, a high frequency component as an example of an electronic component is described in Patent Document 1. This electronic component includes an element body and a planar electrode as an external electrode. The planar electrode is provided on an end surface of the element body. The planar electrode is electrically connected to an internal electrode provided inside the element body.
Patent Document 1: WO 2017/179325

### BRIEF SUMMARY OF THE DISCLOSURE

In conventional electronic components, an internal electrode and a planar electrode are connected through a via conductor provided inside an element body. In the manufacturing process of the electronic component, irregularities are generated on the front surface of the via conductor. Therefore, for example, when the outer edge portion of the planar electrode and the via conductor are connected, the bonding strength between the planar electrode and the via conductor decreases due to non-adhesion of plating, voids at the interface of plating, or the like, and the planar electrode may be turned up. On the other hand, when the via conductor is connected to the central portion of the planar electrode, a decrease in bonding strength can be suppressed. Therefore, in the conventional electronic components, even if the planar electrode is provided at the end portion of the element body, the via conductor needs to be provided closer to the central portion from the end portion of the element body.

However, when the via conductor is provided closer to the central portion from the end portion of the element body, the degree of freedom of arrangement of other via conductors and internal electrodes is limited inside the electronic component. Accordingly, the design for improving the performance of the electronic component becomes difficult.

Therefore, a possible benefit of the present disclosure is to solve the above problems, and to provide an electronic component that can be easily designed for improving performance of the electronic component by increasing a degree of freedom of arrangement of a via conductor and an internal electrode inside the electronic component.

In order to achieve the possible benefit, an electronic component according to a aspect of the present disclosure including: an element body having an outer surface; a via conductor configured to penetrate at least a part of the element body in a thickness direction of the element body, the via conductor provided so that one end surface is flush with an outer surface of the element body; and a columnar electrode having a base end portion electrically connected to the one end surface of the via conductor, so as to protrude in the thickness direction from an outer surface of the element body. A length in the thickness direction of the columnar electrode is longer than a maximum width in a cross section orthogonal to the thickness direction of the columnar electrode.

In addition, a method for manufacturing an electronic component according to a aspect of the present disclosure including: a first filling step of providing at least one first hole portion in at least one sheet not burned out and filling each of the first hole portions with a first conductive paste to form a via conductor; a second filling step of providing at least one second hole portion in at least one resin sheet and filling each of the second hole portions with a second conductive paste; a lamination step of laminating the resin sheet on the sheet so that the first hole portion and the second hole portion communicate with each other after the first filling step and the second filling step to form a laminate; and a firing step of firing the laminate to burn out the resin sheet, forming, as an element body, a portion of the not-burned-out sheet, and forming, as a columnar electrode, the second conductive paste filled in the second hole portion of the burned-out resin sheet.

According to the present disclosure, by increasing the degree of freedom of arrangement of the via conductors and the internal electrodes inside the electronic component, it is possible to facilitate designing for improving the performance of the electronic component.

### BRIEF DESCRIPTION OF THE SEVERAL VIEWS OF THE DRAWINGS

FIG. 1 is a bottom view schematically showing an electronic component according to a first embodiment of the present disclosure.

FIG. 2 is a cross-sectional view taken along line A1-A1 of the electronic component in FIG. 1.

FIG. 3 is a front view schematically showing a circuit module in which the electronic component in FIG. 1 is mounted on a board.

FIG. 4 is a cross-sectional view of a sheet and a carrier film schematically showing an example of the method for manufacturing the electronic component according to the first embodiment of the present disclosure.

FIG. 5 is a cross-sectional view showing a step following FIG. 4.

FIG. 6 is a cross-sectional view showing a step following FIG. 5.

FIG. 7 is a cross-sectional view showing a step following FIG. 6.

FIG. 8 is a cross-sectional view of a resin sheet and a carrier film schematically showing an example of the method for manufacturing the electronic component according to the first embodiment of the present disclosure.

FIG. 9 is a cross-sectional view showing a step following FIG. 8.

FIG. 10 is a cross-sectional view showing a step following FIG. 9.

FIG. 11 is a cross-sectional view showing an example of a step following FIGS. 7 and 10.

FIG. 12 is a cross-sectional view showing another example of a step following FIGS. 7 and 10.

FIG. 13 is a cross-sectional view showing an example of a step following FIG. 11.

FIG. 14 is a cross-sectional view showing an example of a step following FIG. 13.

FIG. 15 is a cross-sectional view showing still another example of a step following FIGS. 7 and 10.

FIG. 16 is a cross-sectional view showing an example of a step following FIG. 15.

FIG. 17 is a cross-sectional view showing an example of a step following FIG. 16.

FIG. 18 is a cross-sectional view showing an example of a step following FIG. 17.

FIG. 19 is a cross-sectional view schematically showing an electronic component according to a first modification of the first embodiment of the present disclosure.

FIG. 20 is a cross-sectional view schematically showing an electronic component according to a second modification of the first embodiment of the present disclosure.

FIG. 21 is a cross-sectional view schematically showing an example of a method for manufacturing the electronic component shown in FIG. 20.

FIG. 22 is a cross-sectional view schematically showing an electronic component according to a third modification of the first embodiment of the present disclosure.

FIG. 23 is a cross-sectional view schematically showing an example of a method for manufacturing the electronic component shown in FIG. 22.

FIG. 24 is a cross-sectional view of an electronic component according to a fourth modification of the first embodiment of the present disclosure.

FIG. 25 is a bottom view schematically showing an electronic component according to a second embodiment of the present disclosure.

FIG. 26 is a bottom view schematically showing an electronic component according to a third embodiment of the present disclosure.

FIG. 27 is a bottom view schematically showing an electronic component according to a first modification of the third embodiment of the present disclosure.

### DETAILED DESCRIPTION OF THE DISCLOSURE

According to a first aspect of the present disclosure, provided is an electronic component including: an element body having an outer surface; a via conductor configured to penetrate at least a part of the element body in a thickness direction of the element body, the via conductor provided so that one end surface is flush with an outer surface of the element body; and a columnar electrode having a base end portion electrically connected to the one end surface of the via conductor, so as to protrude in the thickness direction from an outer surface of the element body. A length in the thickness direction of the columnar electrode is longer than a maximum width in a cross section orthogonal to the thickness direction of the columnar electrode.

According to a second aspect of the present disclosure, provided is the electronic component according to the first aspect, in which the columnar electrode has a tapered portion whose outer shape gradually narrows from a tip portion on an opposite side from the base end portion toward the base end portion in the thickness direction.

According to a third aspect of the present disclosure, provided is the electronic component according to the first aspect, in which the columnar electrode has a tapered portion whose outer shape gradually narrows from a place closer to the base end portion than to a tip portion on an opposite side from the base end portion to the tip portion in the thickness direction.

According to a fourth aspect of the present disclosure, provided is the electronic component according to any one of the first to third aspects further including a covering portion configured to cover an outer circumferential surface around the thickness direction of the columnar electrode.

According to a fifth aspect of the present disclosure, provided is the electronic component according to any one of the first to fourth aspects further including a plurality of the columnar electrodes on an outer surface of the element body. A size of a cross section orthogonal to the thickness direction of at least one columnar electrode among a plurality of the columnar electrodes is different from a size of the cross section of the other columnar electrode.

According to a sixth aspect of the present disclosure, provided is the electronic component according to any one of the first to fifth aspects, in which the columnar electrode includes: at least one first columnar electrode, and a plurality of second columnar electrodes arranged so as to surround the first columnar electrodes as viewed in a direction orthogonal to an outer surface of the element body.

According to a seventh aspect of the present disclosure, provided is the electronic component according to the sixth aspect, in which an outer surface of the element body has a plurality of surfaces including a bottom surface on which the columnar electrode is provided. A surface excluding the bottom surface among outer surfaces of the element body and an opposite side from the first columnar electrode with respect to the plurality of second columnar electrodes on the bottom surface are covered with a shield film. The shield film is in contact with the plurality of second columnar electrodes.

According to an eighth aspect of the present disclosure, provided is the electronic component according to any one of the first to seventh aspects, in which the columnar electrode and the via conductor are connected so that an axis of the columnar electrode and an axis of the via conductor are coaxial.

According to a ninth aspect of the present disclosure, provided is a circuit module including: the electronic component according to any one of the first to eighth aspects; and a board on which the electronic component is mounted through the columnar electrode.

According to a tenth aspect of the present disclosure, provided is a method for manufacturing an electronic component, the method including: a first filling step of providing at least one first hole portion in at least one sheet not burned out and filling each of the first hole portions with a first conductive paste to form a via conductor; a second filling step of providing at least one second hole portion in at least one resin sheet and filling each of the second hole portions with a second conductive paste; a lamination step of laminating the resin sheet on the sheet so that the first hole portion and the second hole portion communicate with each other after the first filling step and the second filling step to form a laminate; and a firing step of firing the laminate to burn out the resin sheet, forming, as an element body, a portion of the not-burned-out sheet, and forming, as a columnar electrode, the second conductive paste filled in the second hole portion of the burned-out resin sheet.

According to an 11th aspect of the present disclosure, provided is the method for manufacturing an electronic component according to the 10th aspect, in the lamination step, a coupled laminate in which a plurality of the laminates are integrated in a state of being arranged on the same plane is formed. A separation step of dicing the coupled laminate to form a plurality of the laminates after the lamination step is further included.

According to a 12th aspect of the present disclosure, provided is the method for manufacturing an electronic component according to the 11th aspect, in the separation step, the coupled laminate is diced into a plurality of the laminates so that an outer edge portion of the sheet and an outer edge portion of the resin sheet are flush with each other as viewed in a laminating direction.

According to a 13th aspect of the present disclosure, provided is the method for manufacturing an electronic component according to the 11th aspect, in the separation step, the coupled laminate is diced into a plurality of the laminates so that the sheet protrudes outward from the resin sheet as viewed in the laminating direction.

Hereinafter, embodiments of the present disclosure will be described with reference to the drawings. It should be noted that the present disclosure is not limited to the following embodiments. In addition, in the drawings, substantially the same members are denoted by the same reference numerals, whereby the description thereof will be omitted.

In addition, in the following description, terms indicating directions such as “vertical”, “bottom surface”, “top surface”, “side surface”, and “width” are used for convenience of description. However, these terms are not intended to limit the usage state or the like of the electronic component according to the present disclosure.

### First Embodiment

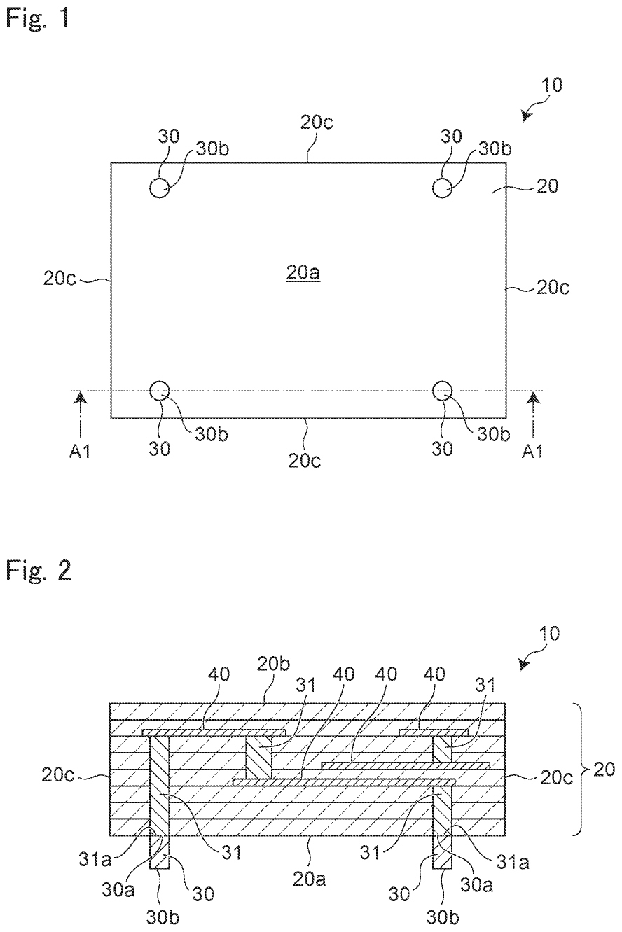

An electronic component according to an embodiment of the present disclosure will be described with reference to FIGS. 1 and 2. FIG. 1 is a bottom view schematically showing an electronic component according to a first embodiment of the present disclosure. FIG. 2 is a cross-sectional view taken along line A1-A1 of the electronic component in FIG. 1.

As shown in FIGS. 1 and 2, an electronic component 10 according to the present first embodiment includes an element body 20 and a columnar electrode 30.

In the present first embodiment, the element body 20 has a rectangular parallelepiped shape. The element body 20 is made of, for example, low temperature co-fired ceramics (LTCC) being an example of ceramics. The element body 20 has a bottom surface 20a, a top surface 20b, and four side surfaces 20c as outer surfaces. The top surface 20b is provided so as to be parallel or substantially parallel to the bottom surface 20a. Each of the four side surfaces 20c is connected to the bottom surface 20a and the top surface 20b. The element body 20 is formed as a laminated structure. In the present first embodiment, the element body 20 has an 8-layer structure. That is, the element body 20 is formed by integrating eight laminated sheets. The thickness direction of the element body 20 is the same as the laminating direction of the sheets.

Four via conductors 31 are provided inside the element body 20. The via conductor 31 is filled in a through hole formed in the sheet and having a circular shape in a plan view. The term “in a plan view” means viewing in a direction orthogonal to the front surface of the sheet. That is, the via conductor 31 has a cylindrical shape. The axis of the via conductor 31 passes through the center of a circle being a cross section of the via conductor 31 and extends in a direction orthogonal to the cross section.

The via conductor 31 is made of a conductive material. The conductive material constituting the via conductor 31 is, for example, a mixture of metal powder such as copper (Cu), a plasticizer, and a binder. The binder is, for example, an organic solvent or the like.

Each via conductor 31 is provided ranging between a plurality of layers. In the present first embodiment, one via conductor 31 ranging over six sheets, two via conductors 31 ranging over three sheets, and one via conductor 31 ranging over two sheets are provided inside the element body 20. The end portions 31a of the two via conductors 31 are exposed to the bottom surface 20a. Here, the end portion 31a is one end surface of the via conductor 31. The other two via conductors 31 are not exposed to the bottom surface 20a and are completely embedded in the element body 20. That is, the via conductor 31 penetrates at least a part of the element body 20 in the thickness direction of the element body. The end portion 31a of the via conductor 31 is flush with the bottom surface 20a of the element body 20. That is, the end portion 31a of the via conductor 31 is flush with the outer surface of the element body 20.

Four internal electrodes 40 are provided inside the element body 20. The internal electrode 40 is formed on a front surface or a back surface of a sheet constituting the element body 20. In the present first embodiment, two internal electrodes 40 are formed on the front surface of the third sheet from the top of the paper surface in FIG. 2 among the eight sheets. In addition, one internal electrode 40 is formed on each of the front surfaces of the fifth and sixth sheets from the top of the paper surface in FIG. 2. Each internal electrode 40 is electrically connected to each other through a via conductor 31.

The columnar electrode 30 is connected to the end portion 31a exposed to the bottom surface 20a of the via conductor 31. The columnar electrode 30 is made of a conductive material. The conductive material constituting the columnar electrode 30 is, for example, obtained by mixing metal powder such as Cu, glass powder, a plasticizer, and a binder. That is, the columnar electrode 30 is electrically connected to the via conductor 31.

The columnar electrode 30 protrudes from the end portion 31a of the via conductor 31 in a direction orthogonal to the back surface of the sheet. That is, the columnar electrode 30 protrudes from the bottom surface 20a of the element body 20 and is exposed. That is, the columnar electrode 30 protrudes from the outer surface of the element body 20 in the thickness direction of the element body 20. The columnar electrode 30 has a base end portion 30a and a tip portion 30b. The base end portion 30a is connected to the end portion 31a of the via conductor 31. The base end portion 30a of the columnar electrode 30 is electrically connected to the end portion 31a of the via conductor 31. That is, the base end portion 30a is provided on the fixed end side of the columnar electrode 30. The tip portion 30b is provided on the free end side of the columnar electrode 30. That is, the tip portion 30b is provided on the opposite side from the base end portion 30a in the thickness direction of the element body 20.

The columnar electrode 30 has a cylindrical shape. The axis of the columnar electrode 30 passes through the center of a circle being a cross section of the columnar electrode 30 and extends in a direction orthogonal to the cross section. That is, the protruding direction of the columnar electrode 30 is the axial direction of the columnar electrode 30 having a cylindrical shape. The axial direction of the columnar electrode 30 is the same as the thickness direction of the element body 20 described above. The axial length of the columnar electrode 30 is longer than the diameter of a circle being a cross section of the columnar electrode 30. That is, the length in the thickness direction of the columnar electrode 30 is longer than the maximum width in the cross section orthogonal to the thickness direction of the columnar electrode 30.

The columnar electrode 30 and the via conductor 31 are connected so that the axis of the columnar electrode 30 and the axis of the via conductor 31 are coaxial. The term “coaxial” includes substantially coaxial.

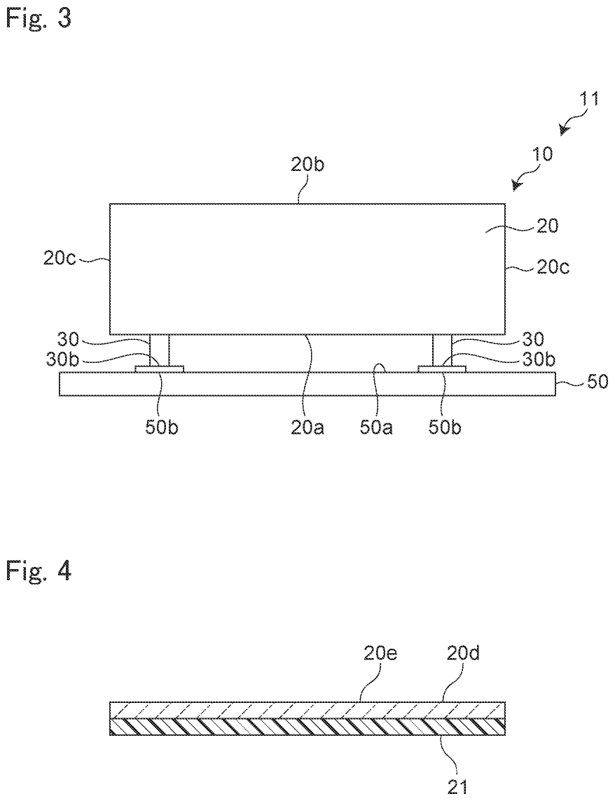

The electronic component according to the present first embodiment is used by being mounted on a board, for example. FIG. 3 is a front view schematically showing a circuit module 11 in which the electronic component 10 in FIG. 1 is mounted on a board.

The circuit module 11 includes an electronic component 10 and a board 50. The board 50 has a mounting surface 50a. The mounting surface 50a has an electrode 50b. The electronic component 10 is connected to the board 50 through the columnar electrode 30. Specifically, the tip portion 30b of the columnar electrode 30 and the electrode 50b of the board 50 are connected.

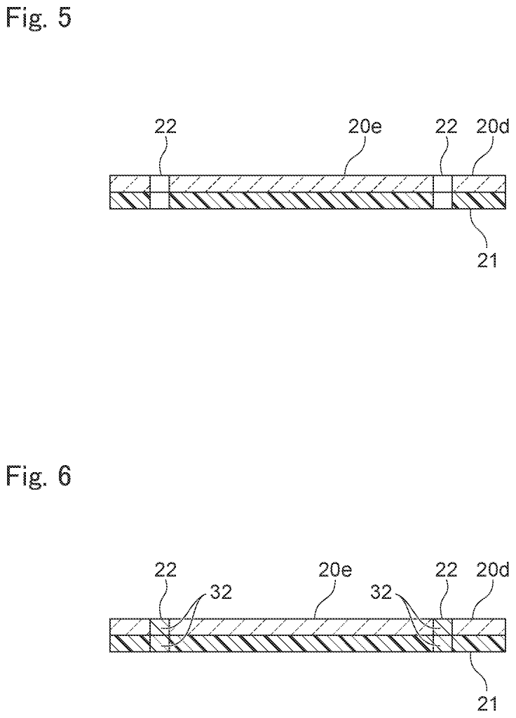

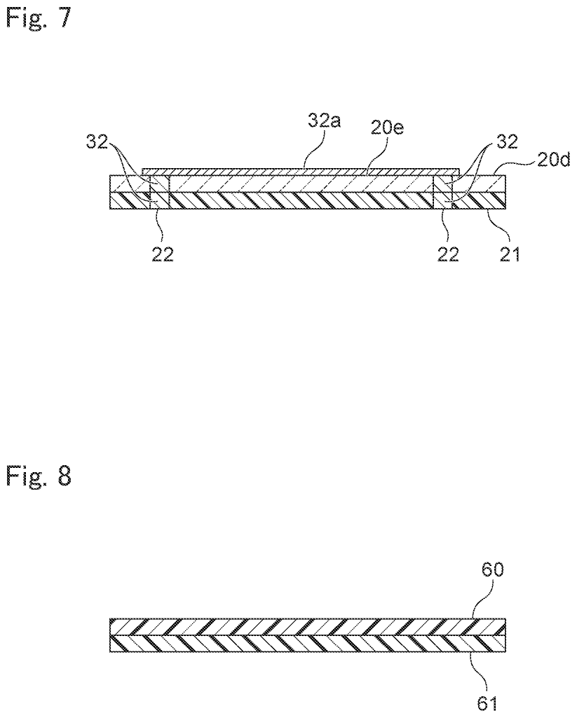

Next, a method for manufacturing an electronic component according to the first embodiment of the present disclosure will be described. FIGS. 4 to 18 are cross-sectional views schematically showing each step which is an example of the method for manufacturing the electronic component according to the first embodiment of the present disclosure. First, each step being an example of the method for manufacturing the electronic component according to the first embodiment of the present disclosure will be described with reference to FIGS. 4 to 7. FIG. 4 is a cross-sectional view of a sheet and a carrier film schematically showing an example of the method for manufacturing the electronic component according to the first embodiment of the present disclosure. FIG. 5 is a cross-sectional view showing a step following FIG. 4. FIG. 6 is a cross-sectional view showing a step following FIG. 5. FIG. 7 is a cross-sectional view showing a step following FIG. 6.

First, as shown in FIG. 4, a sheet 20d provided on the carrier film 21 is prepared. The carrier film 21 is made of, for example, polyethylene terephthalate (PET). The carrier film 21 is removed when the sheet 20d is laminated in the lamination step described below. The sheet 20d is made of a material that does not burn out in the firing step described below. The sheet 20d is, for example, a green sheet made of LTCC being an example of ceramics or the like. In this case, slurry obtained by mixing ceramic powder, plasticizer, and binder in any amounts is prepared. The prepared slurry is applied onto the carrier film 21 and formed into a sheet shape, thereby forming the sheet 20d. As a method of applying the slurry to the carrier film 21, for example, a lip coater, a doctor blade, or the like can be used. In the present first embodiment, the sheet 20d is formed so that the thickness of the sheet 20d is 5 μm or more and 100 μm or less, but the thickness of the sheet 20d is not limited to the above-described thickness (5 μm or more and 100 μm or less).

Next, as shown in FIG. 5, the first hole portion 22 is formed at any position of the sheet 20d. The first hole portion 22 can be formed by, for example, punching or laser machining. In FIG. 5, the first hole portions 22 are provided at two places. In the present first embodiment, the first hole portion 22 has a circular cross section. In the present first embodiment, the diameter of the first hole portion 22 is 20 μm or more and 200 μm or less, but the diameter of the first hole portion 22 is not limited to the above-described diameter (20 μm or more and 200 μm or less).

Next, as shown in FIG. 6, each of the first hole portions 22 is filled with the first conductive paste 32. The first conductive paste 32 is formed by mixing metal powder such as Cu, plasticizer, and binder, for example. The binder is, for example, an organic solvent or the like.

Next, as shown in FIG. 7, the third conductive paste 32a is printed on the main surface 20e of the sheet 20d. The third conductive paste 32a is formed by mixing Cu powder, glass powder, plasticizer, and binder, for example. The binder is, for example, an organic solvent or the like. The third conductive paste 32a is printed by, for example, screen printing or gravure printing.

The step described above corresponds to the first filling step.

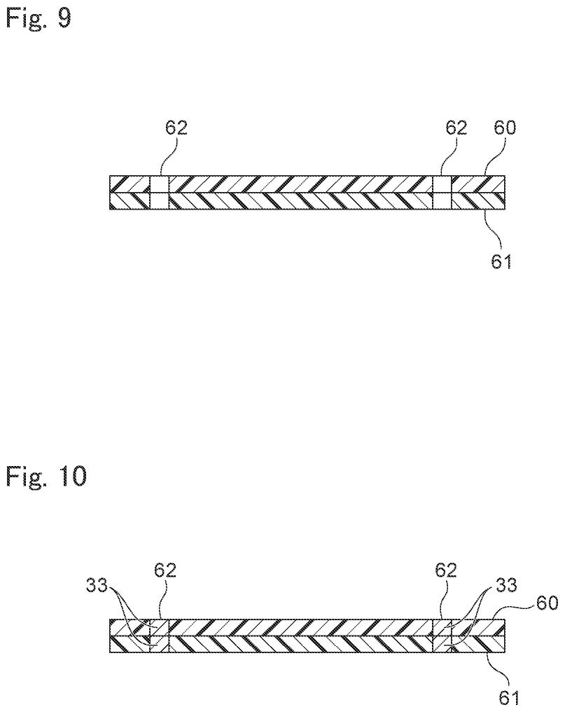

Subsequently, the method for manufacturing the electronic component according to the first embodiment of the present disclosure will be further described with reference to FIGS. 8 to 10. FIG. 8 is a cross-sectional view of a resin sheet 60 and a carrier film 61 schematically showing an example of the method for manufacturing the electronic component according to the first embodiment of the present disclosure. FIG. 9 is a cross-sectional view showing a step following FIG. 8. FIG. 10 is a cross-sectional view showing a step following FIG. 9.

First, as shown in FIG. 8, a resin sheet 60 provided on the carrier film 61 is prepared. The carrier film 61 is made of, for example, polyethylene terephthalate (PET). The carrier film 61 is removed when the resin sheet 60 is laminated in the lamination step described below. The resin sheet 60 is made of a material that burns out in a firing step described below. The resin sheet 60 is made of, for example, an acrylic resin. In the present first embodiment, the thickness of the resin sheet 60 is 5 μm or more and 100 μm or less, but is not limited thereto.

Next, as shown in FIG. 9, the second hole portion 62 is formed at any position of the resin sheet 60. The second hole portion 62 can be formed by, for example, punching or laser machining. In FIG. 9, the second hole portion 62 are provided at two places. In the present first embodiment, the second hole portion 62 has a circular cross section. In the present first embodiment, the diameter of the second hole portion 62 is 20 μm or more and 200 μm or less, but is not limited thereto.

Next, as shown in FIG. 10, each of the second hole portions 62 is filled with the second conductive paste 33. The second conductive paste 33 is formed by mixing Cu powder, glass powder, plasticizer, and binder, for example. The binder is, for example, an organic solvent or the like.

The step described above corresponds to the second filling step.

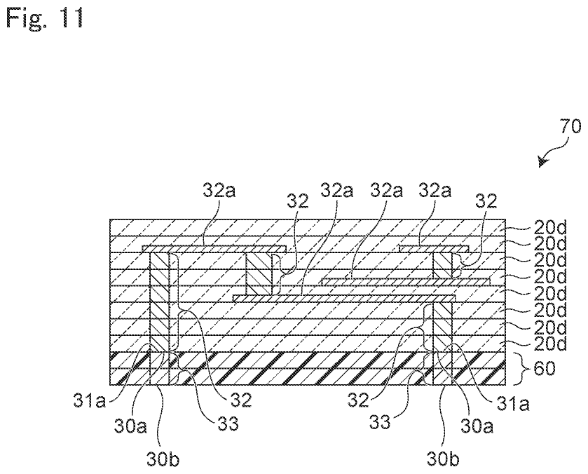

After only the desired number of sheets 20d and resin sheets 60 are prepared in a manner as described with reference to FIGS. 4 to 10, the step shown in FIG. 11 is executed. FIG. 11 is a cross-sectional view showing an example of a step following FIGS. 7 and 10. As shown in FIG. 11, the resin sheet 60 is laminated on the sheet 20d, thereby forming a laminate 70. The carrier film 21 is removed when the sheet 20d is laminated. In addition, the carrier film 61 is removed when the resin sheet 60 is laminated. The laminate 70 is formed by, for example, a method such as pressure bonding. The positions of the first hole portions 22 on the sheet 20d correspond to the positions of the respective second hole portions 62 on the resin sheet 60. Accordingly, when the resin sheet 60 is laminated on the sheet 20d, the first hole portion 22 and the second hole portion 62 communicate with each other. Therefore, the first conductive paste 32 and the second conductive paste 33 are connected.

By laminating the resin sheet 60 on the sheet 20d, the first conductive paste 32 is formed as the via conductor 31, and the third conductive paste 32a is formed as the internal electrode 40.

The step described above corresponds to the lamination step.

Thereafter, the laminate 70 is fired. Accordingly, the resin sheet 60 is burned out. As a result, the second conductive paste 33 is formed as the columnar electrode 30. On the other hand, the sheet 20d is not burned out by firing. As a result, the sheet 20d and the via conductor 31 and the internal electrode 40 formed on the sheet 20d are formed as the element body 20. By this manufacturing method, the electronic component 10 shown in FIG. 2 is formed.

The step described above corresponds to the firing step.

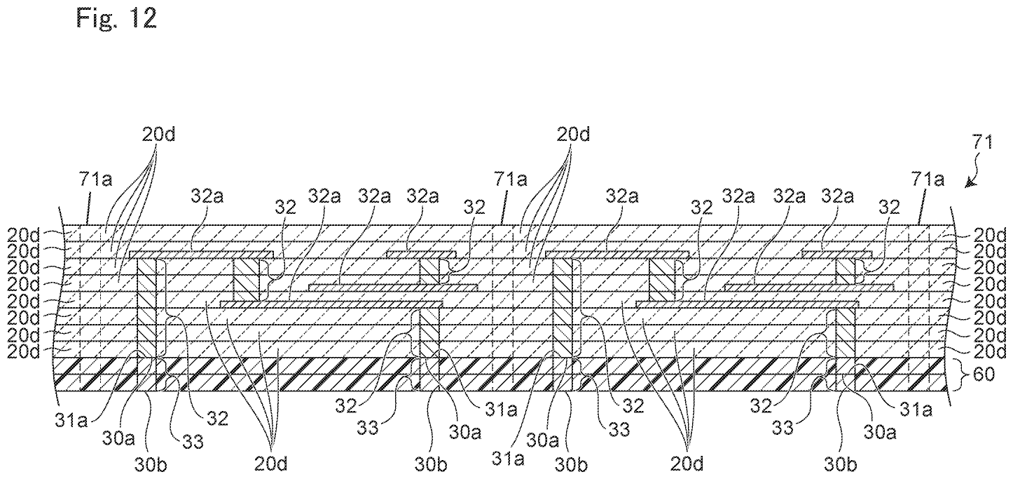

So far, the step of forming one laminate 70 shown in FIG. 11 has been described through the steps shown in FIGS. 4 to 10. Another method for obtaining the laminate 70 will be described with reference to FIG. 12. FIG. 12 is a cross-sectional view showing another example of a step following FIGS. 7 and 10. In FIG. 12, a coupled laminate 71 is formed so that laminates such as the laminate 70 shown in FIG. 11 are continuously provided.

The coupled laminate 71 is formed by laminating a coupled sheet and a coupled resin sheet. The coupled sheet is formed by plurally arranging a plurality of sheets 20d in a plan view. The plurality of sheets 20d are arranged at intervals. The coupled resin sheet is formed by plurally arranging a plurality of resin sheets 60 in a plan view. The plurality of resin sheets 60 are arranged at intervals. That is, the coupled laminate 71 is formed by integrating a plurality of laminates 70 in a state of being arranged on the same plane.

In a state where the coupled sheet and the coupled resin sheet are laminated, the region between the plurality of sheets 20d described above and the region between the plurality of resin sheets 60 described above are the same in a plan view. Accordingly, a cut line 71a indicated by a broken line in FIG. 12 is formed. By cutting the coupled laminate at a uniform width of the cut line 71a, a plurality of diced laminates 70 as shown in FIG. 11 can be obtained. In each laminate 70 thus obtained, the outer edge portion of the sheet 20d and the outer edge portion of the resin sheet 60 are flush with each other.

The step described above corresponds to the separation step.

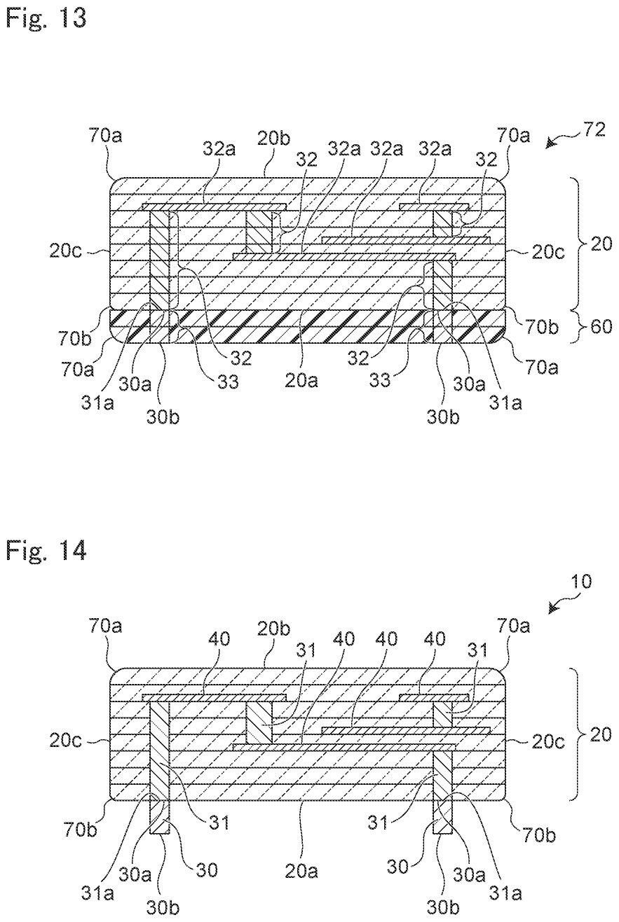

Next, steps to follow will be further described with reference to FIGS. 13 and 14. FIG. 13 is a cross-sectional view showing an example of a step following FIG. 11. FIG. 14 is a cross-sectional view showing an example of a step following FIG. 13.

The laminate 70 shown in FIG. 11 is subjected to, for example, polishing processing such as barrel processing. Accordingly, as shown in FIG. 13, a laminate 72 is obtained. In the polishing processing, the bent portions of the outer surfaces of the sheet 20d and the resin sheet 60 are subjected to chamfering. Accordingly, the laminate 72 has rounded work portions 70a and 70b. The electronic component 10 shown in FIG. 14 is obtained by firing the laminate 72 shown in FIG. 13. At this time, the radius of the curved portion of the rounded work portion 70b on the bottom surface 20a side of the element body 20 is smaller than the radius of the curved portion of the rounded work portion 70a on the top surface 20b side of the element body 20. This is because the outer edge portion of the resin sheet 60 in a plan view is connected to the outer edge portion of the sheet 20d in a plan view when the polishing processing is executed, and thus, large polishing cannot be performed.

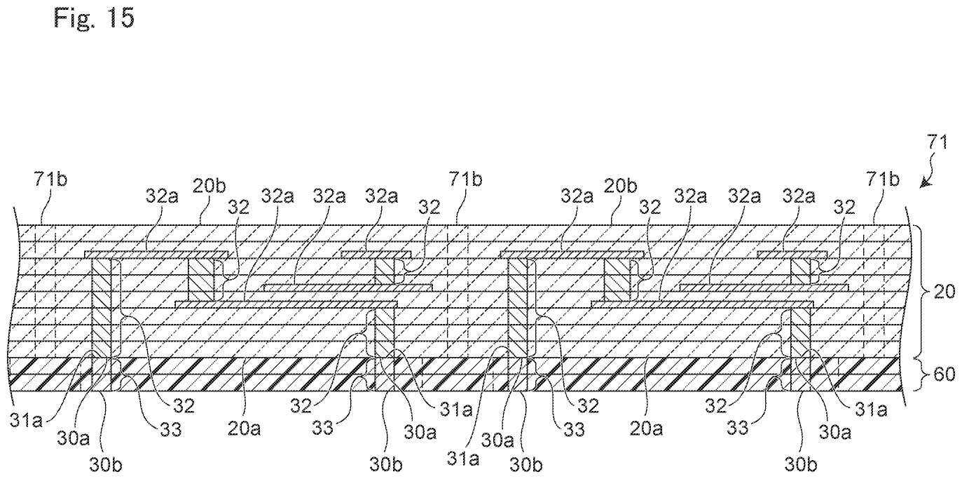

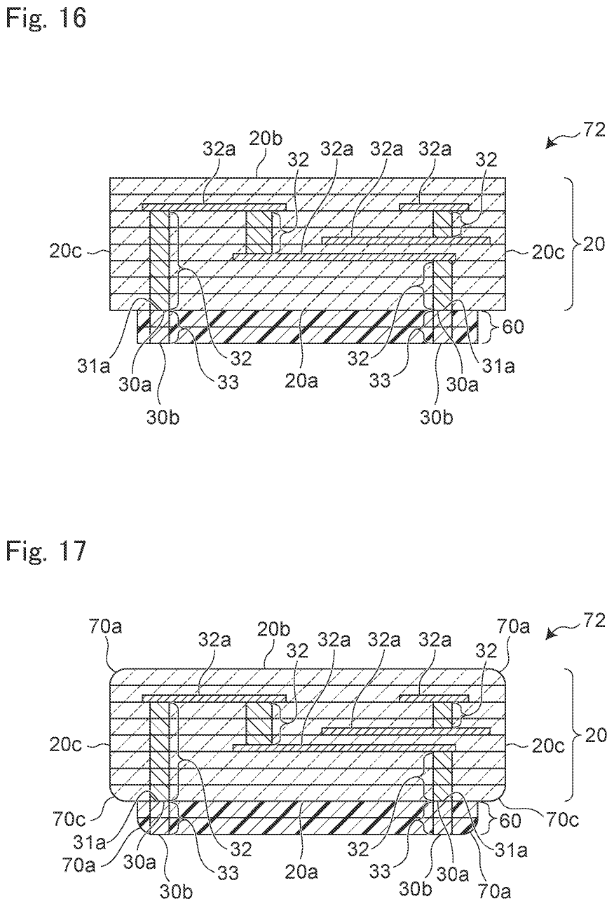

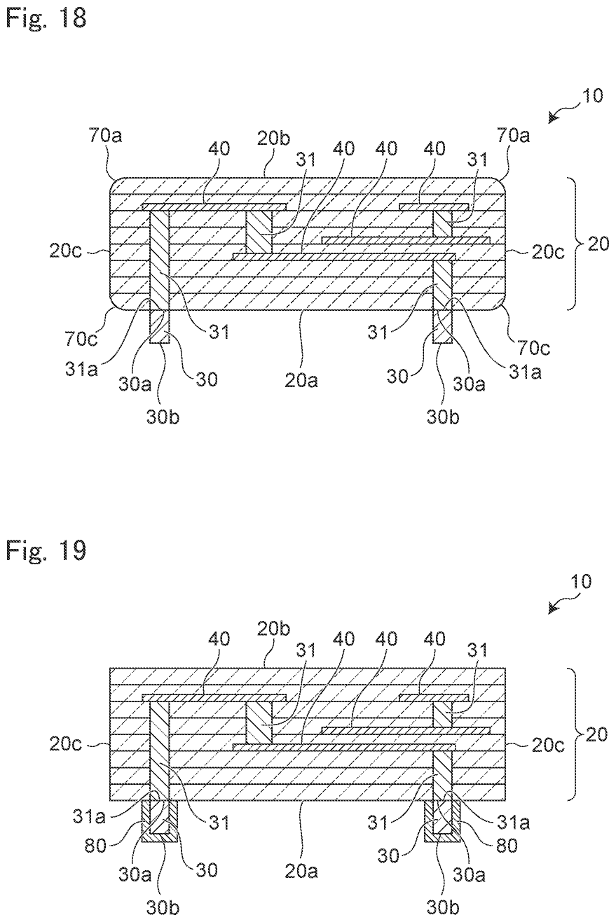

Furthermore, with reference to FIG. 15, a dicing step different from the dicing step described with reference to FIG. 12 will be described. In addition, with reference to FIGS. 16 to 18, another polishing processing step will be described. FIG. 15 is a cross-sectional view showing still another example of a step following FIGS. 7 and 10. FIG. 16 is a cross-sectional view showing a step following FIG. 15. FIG. 17 is a cross-sectional view showing an example of a step following FIG. 16. FIG. 18 is a cross-sectional view showing an example of a step following FIG. 17.

The coupled laminate 71 is cut along a cut line 71b (indicated by a broken line in FIG. 15) having a width different from that in FIG. 12. In the cut line 71b, the cut width in the resin sheet 60 is larger than the cut width in the laminated portion of the sheet 20d. A plurality of laminates 72 (see FIG. 16) are obtained by being diced along these cut lines 71b. In the laminate 72 shown in FIG. 16, the length in the width direction (the left-right direction on the paper surface in FIG. 16) of the laminated portion of the sheet 20d is longer than the length in the width direction of the laminated portion of the resin sheet 60. That is, in the laminate 72 shown in FIG. 16, the sheet 20d protrudes outward from the resin sheet 60 in a plan view.

Next, polishing processing such as barrel processing is performed. In the polishing processing, the bent portions of the outer surfaces of the sheet 20d and the resin sheet 60 are subjected to chamfering. Accordingly, the laminate 72 having the rounded work portions 70a and 70c as shown in FIG. 17 is formed. Thereafter, the laminate 72 shown in FIG. 17 is fired. Accordingly, the electronic component 10 shown in FIG. 18 is obtained. At this time, as shown in FIG. 18, the radius of the curved portion of the rounded work portion 70c on the bottom surface 20a side of the element body 20 has substantially the same size as the radius of the curved portion of the rounded work portion 70a on the top surface 20b side of the element body 20. This is because the outer edge portion of the resin sheet 60 in a plan view is not connected to the outer edge portion of the sheet 20d in a plan view when the polishing processing is executed, and thus, large polishing can be performed.

(First Modification)

A first modification of the present first embodiment will be described with reference to FIG. 19. FIG. 19 is a cross-sectional view schematically showing an electronic component according to a first modification of the first embodiment of the present disclosure.

As shown in FIG. 19, a portion where the columnar electrode 30 is exposed from the bottom surface 20a of the element body 20 is covered with plating 80. The plating 80 is made of, for example, gold plating. According to this configuration, the columnar electrode 30 can be protected, and solder can be connected to the columnar electrode 30 when the electronic component 10 is mounted.

(Second Modification)

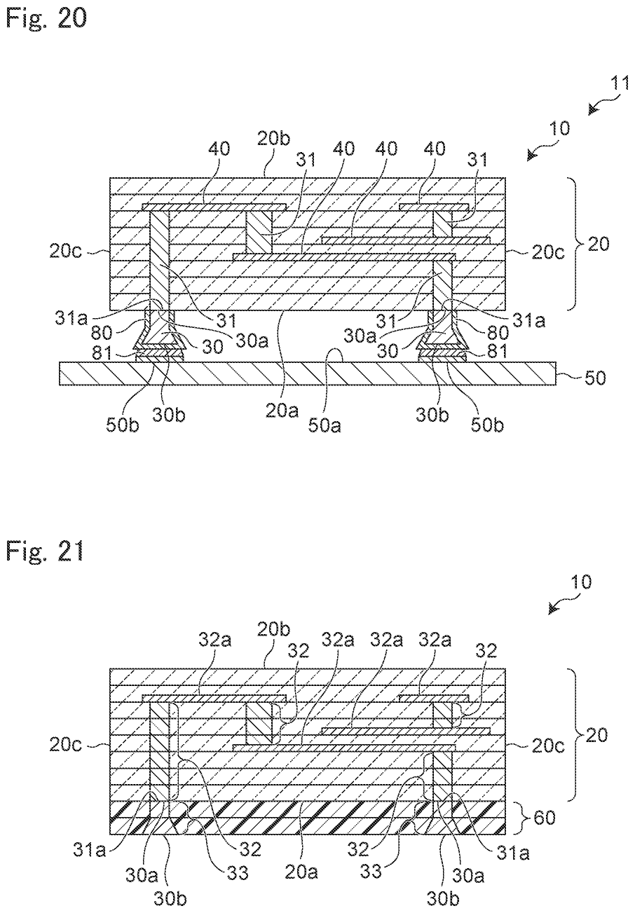

A second modification of the present first embodiment will be described with reference to FIGS. 20 and 21. FIG. 20 is a cross-sectional view schematically showing an electronic component according to a second modification of the first embodiment of the present disclosure. FIG. 21 is a cross-sectional view schematically showing an example of a method for manufacturing the electronic component shown in FIG. 20.

As shown in FIG. 20, the columnar electrode 30 is formed in a tapered shape so that the outer shape gradually narrows from the tip portion 30b toward the base end portion 30a in the axial direction of the columnar electrode 30. That is, the columnar electrode 30 has a tapered portion whose outer shape gradually narrows from the tip portion 30b toward the base end portion 30a. The portion where the columnar electrode 30 is exposed from the element body 20 is covered with plating 80. When the electronic component 10 is mounted on the board 50 as the circuit module 11, the tip portion 30b of the columnar electrode 30 is connected to the electrode 50b of the board 50 through the plating 80 and the solder 81.

When the electronic component 10 having the columnar electrode 30 as shown in FIG. 20 is formed, as shown in FIG. 21, the outermost resin sheet 60 among the laminated portion of the resin sheet 60 is provided with a tapered second hole portion, and the second conductive paste 33 is filled therein.

(Third Modification)

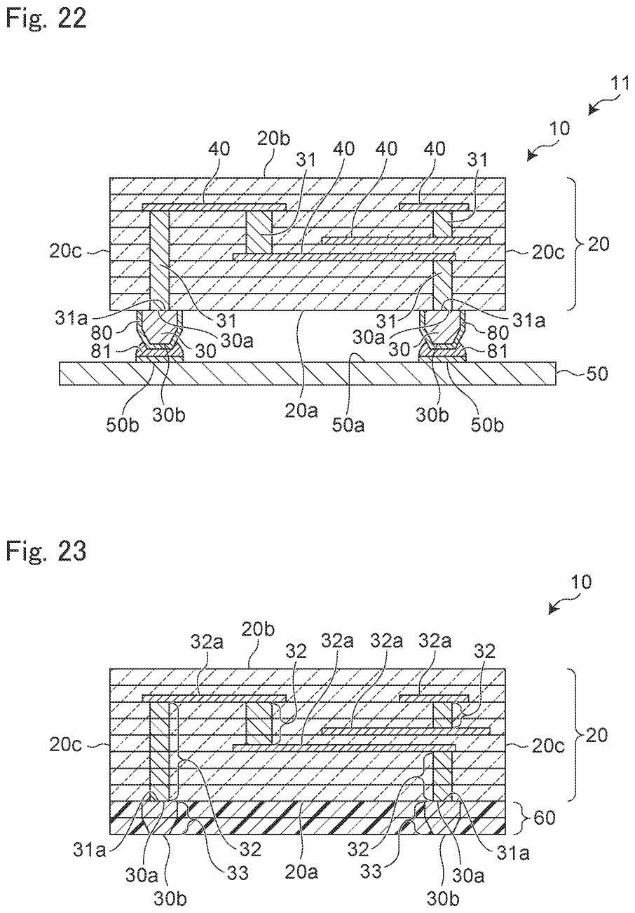

A third modification of the present first embodiment will be described with reference to FIGS. 22 and 23. FIG. 22 is a cross-sectional view schematically showing an electronic component according to a third modification of the first embodiment of the present disclosure. FIG. 23 is a cross-sectional view schematically showing an example of a method for manufacturing the electronic component shown in FIG. 22.

In FIG. 22, the columnar electrode 30 is formed in a tapered shape so that the outer shape gradually narrows from the position between the tip portion 30b and the base end portion 30a to the tip portion 30b in the axial direction. That is, the columnar electrode 30 has a tapered portion whose outer shape gradually narrows from a place closer to the base end portion 30a side than to the tip portion 30b to the tip portion 30b. As in the second modification, the portion where the columnar electrode 30 is exposed from the element body 20 is covered with the plating 80.

When the electronic component 10 having the columnar electrode 30 as shown in FIG. 22 is formed, as shown in FIG. 23, the outermost resin sheet 60 is provided with a tapered second hole portion in a direction opposite to the axial direction of the second modification, and the second conductive paste 33 is filled therein.

(Fourth Modification)

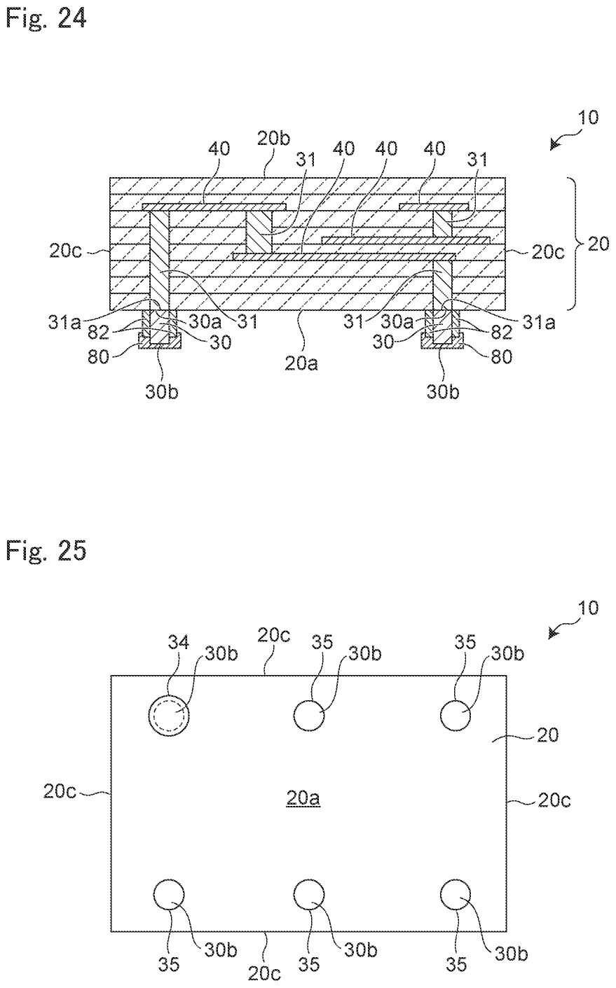

Next, an electronic component according to a fourth modification of the present first embodiment will be further described with reference to FIG. 24. FIG. 24 is a cross-sectional view of an electronic component according to a fourth modification of the first embodiment of the present disclosure.

As shown in FIG. 24, the tip portion 30b is covered with the plating 80 among the places exposed from the element body 20 of the columnar electrode 30. The outer circumferential surface around the axial direction of the columnar electrode 30 is covered with the coating portion 82 by performing the covering treatment. That is, the outer circumferential surface around the thickness direction of the columnar electrode 30 is covered with the coating portion 82 by performing the covering treatment. The coating portion 82 is an example of the covering portion. The covering treatment is, for example, rustproofing treatment in which a nitroxide film, an inorganic film such as silicon dioxide (SiO₂), an organic film such as silicon nitride (SiN), or a resin such as polyimide is provided. The covering treatment is applied before the tip portion 30b of the columnar electrode 30 is covered with the plating 80. Therefore, the plating 80 is not provided at the place where the coating portion 82 is provided by the covering treatment.

The electronic component according to the present first embodiment includes an element body 20 having a bottom surface 20a and a via conductor 31 that penetrates at least a part of the element body 20 in the thickness direction of the element body 20 and is provided so that the end portion 31a is flush with the bottom surface 20a of the element body 20. In addition, the columnar electrode 30 in which the base end portion 30a is electrically connected to the end portion 31a of the via conductor 31 is provided so as to protrude from the bottom surface 20a of the element body 20 in the thickness direction of the element body 20. Furthermore, the length in the thickness direction of the columnar electrode 30 is longer than the maximum width in the cross section orthogonal to the thickness direction of the columnar electrode 30.

According to this configuration, rather than the planar electrode likely to be turned up, the columnar electrode 30 less likely to be turned up is connected to the via conductor 31. Therefore, even if the via conductor 31 is arranged so that the end portion 31a of the via conductor 31 is exposed to the outer edge portion of the bottom surface 20a and the columnar electrode 30 is connected to the end portion 31a, the possibility that the columnar electrode 30 is turned up can be reduced. The via conductor 31 is arranged so that the end portion 31a of the via conductor 31 is exposed to the outer edge portion of the bottom surface 20a, whereby the degree of freedom of arrangement of the via conductor 31 and the internal electrode 40 inside the element body 20 can be increased as compared with the conventional case. As a result, it is possible to facilitate designing for improving the performance of the electronic component 10.

In addition, in the conventional configuration in which the electronic component is mounted on the planar electrode, the planar electrode is bent by heat generated during soldering, so that the bottom surface of the element body of the electronic component is also bent, and the bottom surface of the element body of the electronic component may be cracked.

Conventionally, such a problem occurs, but according to the present first embodiment, heat generated during soldering is applied to the tip portion 30b of the columnar electrode 30. Therefore, the base end portion 30a of the columnar electrode 30 and the element body 20 connected to the base end portion 30a are less likely to be affected by heat generated at the time of soldering than the tip portion 30b of the columnar electrode 30 and are less likely to be bent. That is, the bottom surface 20a of the element body 20 is less likely to be bent and crack than the bottom surface of the conventional element body provided with the planar electrode.

In addition, the columnar electrode 30 can function as a pseudo coil in which a conductor is wound around an outer circumferential surface around the axis of the columnar electrode 30 with the axis of the columnar electrode 30 as a winding axis. In the columnar electrode 30, since the axial length of the columnar electrode 30 is longer than the length of the columnar electrode 30 along the direction orthogonal to the axial direction of the columnar electrode 30, the number of turns of the pseudo coil can be increased. Therefore, the columnar electrode 30 can be caused to function as an inductor that generates a large magnetic field as compared with a case where the number of turns of the pseudo coil is small.

Furthermore, the columnar electrode 30 is exposed from the element body 20 of the electronic component 10. In the present first embodiment, air having a lower relative dielectric constant than the ceramics constituting the element body 20 is present around the columnar electrode 30.

Here, since having a structure in which a coil pattern is formed on an insulator, an actual inductor inevitably has a capacitive component due to the insulator. Since an equivalent circuit of such an actual inductor has a form in which an inductance component and a capacitance component are connected in parallel, the inductor self-resonates at a specific frequency. When self-resonating, the inductor cannot function as an inductor. Therefore, the inductor needs to be used in an environment at a self-resonant frequency or less in order to function as an inductor. In addition, since the inductor has a larger self-resonant frequency as the relative dielectric constant of the insulator on which the coil pattern is formed is smaller, the inductor can be used in an environment at a higher frequency.

In the columnar electrode 30 according to the present first embodiment, the insulator corresponds to air having a lower relative dielectric constant than ceramics, and the coil pattern corresponds to a pseudo coil in which a conductor is wound around the outer circumferential surface around the axis of the columnar electrode 30. That is, since the columnar electrode 30 is in contact with air having a low relative dielectric constant to form a pseudo coil, the self-resonant frequency becomes larger, and the columnar electrode 30 can be used in a higher frequency environment.

Therefore, when the columnar electrode 30 is disposed to be exposed from the element body 20 as in the present configuration, the columnar electrode 30 can be caused to function as a high-performance inductor, and the performance of the electronic component 10 can be improved.

In addition, according to the electronic component according to the present first embodiment, the columnar electrode 30 may have a tapered portion whose outer shape gradually narrows from the tip portion 30b opposite to the base end portion 30a toward the base end portion 30a in the thickness direction of the element body 20.

According to this configuration, when the electronic component 10 is mounted on the board 50, the tip portion 30b side of the columnar electrode 30 is widened, and the contact area between the columnar electrode 30 and the board 50 is further increased. Therefore, the connection strength between the columnar electrode 30 and the board 50 can be further improved.

In addition, according to the electronic component according to the present first embodiment, the columnar electrode 30 may have a tapered portion whose outer shape gradually narrows from a place closer to the base end portion 30a side than to the tip portion 30b, opposite to the base end portion 30a, to the tip portion 30b in the thickness direction of the element body 20.

According to this configuration, when the electronic component 10 is mounted on the board 50, the tip portion 30b side of the columnar electrode 30 becomes thin. Therefore, the space occupied by the columnar electrode 30 is reduced on the mounting surface 50a of the board 50. As a result, it is possible to widen a space for arranging other electronic components and forming a wiring pattern on the mounting surface 50a of the board 50.

In addition, a tapered portion is provided on the tip portion 30b side of the columnar electrode 30. In this case, the following effects are produced regardless of the direction of the taper. When the electronic component 10 is mounted on the board 50, it is possible to prevent the solder 81 from wet-spreading toward the base end portion 30a side of the columnar electrode 30 along the axial direction of the columnar electrode 30. Accordingly, it is possible to reduce the occurrence of variations for each position in the axial direction in the diameter of the columnar electrode 30 due to the wet-spread solder 81. As a result, since the value of the inductance of the columnar electrode 30 functioning as an inductor can be stabilized, the performance of the electronic component 10 can be improved.

In addition, the electronic component according to the present first embodiment may further include the coating portion 82 that covers the outer circumferential surface around the thickness direction of the element body 20 of the columnar electrode 30.

According to this configuration, as in the case where the tapered portion is provided on the tip portion 30b side of the columnar electrode 30, it is possible to prevent the solder 81 from wet-spreading toward the base end portion 30a side of the columnar electrode 30 along the thickness direction of the columnar electrode 30.

In addition, according to the electronic component according to the present first embodiment, the columnar electrode 30 and the via conductor 31 may be connected so that the axis of the columnar electrode 30 and the axis of the via conductor 31 are coaxial.

According to this configuration, the strength of the connection portion between the columnar electrode 30 and the via conductor 31 can be increased as compared with the case where the axis of the columnar electrode 30 and the axis of the via conductor 31 are connected so as not to be coaxial. Therefore, the possibility that the electronic component 10 is damaged can be suppressed.

In addition, the circuit module according to the present first embodiment includes the electronic component 10 and the board 50 on which the electronic component 10 is mounted through the columnar electrode 30.

According to this configuration, since the columnar electrode 30 is disposed between the element body 20 of the electronic component 10 and the board 50, the distance between the element body 20 and the board 50 can be increased. Therefore, the propagation of the electromagnetic wave between the board 50 and the electronic component 10 can be suppressed.

The method for manufacturing an electronic component according to the present first embodiment includes a first filling step of providing at least one first hole portion 22 in at least one sheet 20d that does not burn out, and filling each of the first hole portions 22 with the first conductive paste 32 to form the via conductor 31. In addition, a second filling step of providing at least one second hole portion 62 in at least one resin sheet 60 and filling each of the second hole portions 62 with the second conductive paste 33 is included. In addition, a lamination step of laminating the resin sheet 60 on the sheet 20d so that the first hole portion 22 and the second hole portion 62 communicate with each other to form the laminate 70 is included after the first filling step and the second filling step. In addition, a firing step of firing the laminate 70 to burn out the resin sheet 60, forming a portion of the sheet 20d that is not burned out as the element body 20, and forming the second conductive paste 33 filled in the second hole portion 62 of the burned out resin sheet 60 as the columnar electrode 30 is included.

According to this manufacturing method, the columnar electrode 30 having any length can be formed through the firing step according to the number of laminate of the resin sheets 60 in the lamination step. Therefore, the value of the inductance of the columnar electrode 30 functioning as an inductor can be optionally determined.

In addition, the method for manufacturing an electronic component according to the present first embodiment may include a separation step of forming a coupled laminate 71 in which a plurality of laminates 70 are integrated in a state of being arranged on the same plane and dicing the coupled laminate 71 after the lamination step to form a plurality of laminates 70.

According to this manufacturing method, the electronic component 10 can be efficiently manufactured as compared with a case where the laminate 70 is formed one by one.

In addition, according to the method for manufacturing an electronic component according to the present first embodiment, in the separation step, the coupled laminate 71 may be diced into a plurality of laminates 70 so that the outer edge portion of the sheet 20d and the outer edge portion of the resin sheet 60 are flush with each other as viewed in the laminating direction.

According to this manufacturing method, when the rounded work portion is provided by chamfering the corner of the electronic component 10, the rounded work portion 70b provided on the bottom surface 20a side where the columnar electrode 30 of the element body 20 is provided can be made small. Therefore, the columnar electrode 30 and the via conductor 31 can be provided closer to the outer edge portion of the element body 20. As a result, it becomes easy to design for improving the performance of the electronic component 10 by increasing the degree of freedom of arrangement of the via conductors 31 and the internal electrodes 40 inside the element body 20, and the performance of the electronic component 10 can be improved.

In addition, according to the method for manufacturing an electronic component according to the present first embodiment, in the separation step, the coupled laminate 71 may be diced into a plurality of laminates 70 so that the sheet 20d protrudes outward from the resin sheet 60 as viewed in the laminating direction.

According to this manufacturing method, when the corner of the electronic component 10 is chamfered to provide rounded work portions, the rounded work portions 70a and 70c having equal sizes can be provided. As a result, the possibility of damage of the electronic component 10 can be reduced.

It should be noted that the present disclosure is not limited to the first embodiment, and can be implemented in various other aspects. For example, in the first embodiment, the element body 20 includes eight sheets 20d, but the present disclosure is not limited thereto. At least one sheet 20d only needs to be provided.

In addition, in the first embodiment, the element body 20 has a rectangular parallelepiped shape, but the present disclosure is not limited thereto. The element body 20 may have, for example, a cubic shape, a polygonal pyramid shape such as a triangular pyramid shape or a quadrangular pyramid shape, a spherical shape, or the like.

In addition, in the first embodiment, the material constituting the columnar electrode 30 and the material constituting the via conductor 31 are different, but the present disclosure is not limited thereto. For example, the material constituting the columnar electrode 30 and the material constituting the via conductor 31 may be made of a metal body (for example, copper or the like) made of the same material. That is, the columnar electrode 30 and the via conductor 31 are not limited to those configured by filling the hole portion with the conductive paste, and may be an integral metal body such as a metal pin. In other words, in the first embodiment, the columnar electrode 30 and the via conductor 31 are provided separately, but the present disclosure is not limited thereto. For example, the columnar electrode 30 and the via conductor 31 may be integrally provided.

In addition, in the first embodiment, four via conductors 31 are provided in the element body 20, but the present disclosure is not limited thereto. For example, at least one via conductor 31 only needs to be provided.

In addition, in the first embodiment, four internal electrodes 40 are provided in the element body 20, but the number of internal electrodes 40 is not limited to four. For example, at least one internal electrode 40 only needs to be provided.

In addition, in the first embodiment, four via conductors 31 whose end portions 31a are connected to the columnar electrodes 30 are provided, but the number of via conductors 31 connected to the columnar electrodes 30 is not limited to four in the present disclosure. For example, at least one via conductor 31 only needs to be provided.

In addition, in the first embodiment, the electronic component 10 includes four columnar electrodes 30, but the number of the columnar electrodes 30 included in the electronic component 10 is not limited to four in the present disclosure. For example, at least one columnar electrode 30 only needs to be provided.

In addition, in the first embodiment, the columnar electrode 30 has a cylindrical shape, but the present disclosure is not limited thereto. For example, the shape of the columnar electrode 30 may be a quadrangular prism shape. In this case, the length in the thickness direction of the element body 20 of the columnar electrode 30 is longer than the length of the diagonal line of the quadrangle having the maximum width in the cross section of the quadrangular prism shape orthogonal to the thickness direction. That is, in the cross section of the columnar electrode 30 along the direction orthogonal to the thickness direction, the length in the thickness direction of the columnar electrode 30 is longer than the longest distance between two parallel lines in contact with both sides of the cross section. That is, the length in the thickness direction of the columnar electrode 30 is longer than the length along the direction orthogonal to the thickness direction of the columnar electrode 30.

In addition, in the first embodiment, the via conductor 31 is provided over a plurality of sheets 20d, but the present disclosure is not limited thereto. For example, the via conductor 31 only needs to be provided over at least one sheet 20d.

In addition, in the first embodiment, the first hole portion 22 has a circular shape in a plan view, but the present disclosure is not limited thereto. For example, in a plan view, the shape of the first hole portion 22 may be a polygon such as a triangle or a quadrangle, an ellipse, or the like.

In addition, in the first embodiment, in the circuit module 11, the electronic component 10 is mounted on the mounting surface 50a of the board 50, but the present disclosure is not limited thereto. For example, the electronic component 10 may be mounted on the back surface of the mounting surface 50a, or may be mounted on both the mounting surface 50a and the back surface.

In addition, in the first embodiment, the element body 20 is made of ceramics, but the present disclosure is not limited thereto. For example, the element body 20 may be made of a resin base material such as polyimide, fluorine-based resin, or liquid crystal polymer.

In addition, in the second modification and the third modification of the first embodiment, the columnar electrode 30 has a tapered portion on a part of the tip portion 30b side, but the present disclosure is not limited thereto. For example, the columnar electrode 30 may have a tapered portion over the entire region from the tip portion 30b to the base end portion 30a.

In addition, in the first embodiment, the length in the axial direction of the columnar electrode 30 is a length corresponding to the thickness of the two resin sheets 60, but the present disclosure is not limited thereto. For example, in the manufacturing process of the electronic component, when only one resin sheet 60 is laminated, the length in the axial direction of the columnar electrode 30 is a length corresponding to the thickness of one resin sheet 60, and when three resin sheets 60 are laminated, the length in the axial direction of the columnar electrode 30 is a length corresponding to the thickness of three resin sheets 60.

In addition, in the first embodiment, the first to third conductive pastes 32, 33, and 32a are formed of metal powder such as copper, but the present disclosure is not limited thereto. The first to third conductive pastes 32, 33, and 32a may be formed of, for example, metal powder such as silver.

In addition, in the first embodiment, the second to third conductive pastes 33 and 32a are formed of the same material, but the present disclosure is not limited thereto. For example, the second conductive paste 33 forming the columnar electrode 30 may be a conductive paste in which strength is considered more than that of the third conductive paste 32a.

In addition, in the first embodiment, the via conductor 31 and the columnar electrode 30 are formed by laminating the sheet 20d and the resin sheet 60 filled with the conductive paste, but the present disclosure is not limited thereto. For example, the via conductor 31 and the columnar electrode 30 may be formed by filling the conductive paste after laminating the sheet 20d and the resin sheet 60 respectively provided with the first hole portion 22 and the second hole portion 62.

### Second Embodiment

An electronic component 10 according to a second embodiment of the present disclosure is different from that of the first embodiment in that a size of a cross section orthogonal to an axial direction of at least one columnar electrode of a plurality of columnar electrodes is different from a size of the cross section of another columnar electrode. It should be noted that in the second embodiment, the same portions as those of the first embodiment will be denoted by the same reference numerals, description thereof will be omitted, and points different from those of the first embodiment will be described.

FIG. 25 is a bottom view schematically showing an electronic component according to a second embodiment of the present disclosure. As shown in FIG. 25, the electronic component 10 includes one first columnar electrode 34 and five second columnar electrodes 35 protruding and exposed from the bottom surface 20a of the element body 20. The diameter of the cross section of the first columnar electrode 34 orthogonal to the axial direction is larger than the diameter of the cross section of the second columnar electrode 35 orthogonal to the axial direction. Etching or the like is performed on the first columnar electrode 34, and the diameter of the first columnar electrode 34 can be reduced as indicated by a broken line shown in FIG. 25.

(First Modification)

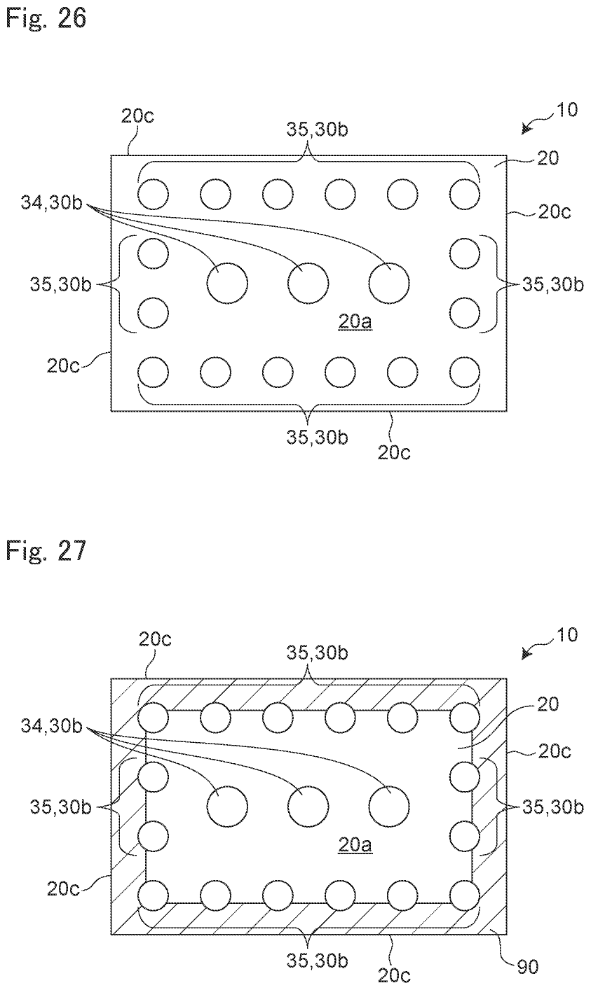

A first modification of the present second embodiment will be described with reference to FIG. 26. FIG. 26 is a bottom view schematically showing an electronic component according to a first modification of the second embodiment of the present disclosure.

As shown in FIG. 26, a plurality of first columnar electrodes 34 and a plurality of second columnar electrodes 35 are provided on the bottom surface 20a of the element body 20. The first columnar electrode 34 is used, for example, as an electrode for a signal line. The second columnar electrode 35 is used, for example, as an electrode connected to a ground potential. In the first modification of the present second embodiment, three first columnar electrodes 34 are surrounded by 16 second columnar electrodes 35 when viewed in a direction orthogonal to the bottom surface 20a.

(Second Modification)

A second modification of the present second embodiment will be described with reference to FIG. 27. FIG. 27 is a bottom view schematically showing an electronic component according to a second modification of the second embodiment of the present disclosure.

The electronic component according to the second modification of the second embodiment includes a shield film 90. The shield film 90 covers the side surface 20c and the top surface 20b. That is, the shield film 90 covers a surface excluding the bottom surface 20a of the element body 20. In addition, the shield film 90 covers the outer edge portion of the bottom surface 20a. The outer edge portion of the bottom surface 20a is the outer edge (side) of the bottom surface 20a and its peripheral portion. In addition, the outer edge portion of the bottom surface 20a is on the opposite side from the first columnar electrode 34 with respect to the second columnar electrode 35 on the bottom surface 20a. The shield film 90 formed on the outer edge portion of the bottom surface 20a is in contact with the second columnar electrode 35 from the outer edge portion side of the bottom surface 20a.

The electronic component according to the present second embodiment includes the first columnar electrode 34 and the second columnar electrode 35 on the bottom surface 20a of the element body 20. In addition, the size of the cross section orthogonal to the thickness direction of the element body 20 of at least one first columnar electrode 34 of the first columnar electrodes 34 and the second columnar electrodes 35 is different from the size of the cross section of the second columnar electrode 35.

According to this configuration, for example, by setting the size of the cross section related to each of the first columnar electrode 34 and the second columnar electrode 35 to various sizes, it is possible to provide the first columnar electrode 34 and the second columnar electrode 35 having performance as a desired inductor.

In addition, according to the electronic component according to the present second embodiment, the columnar electrode may include at least one first columnar electrode 34 and a plurality of second columnar electrodes 35 arranged to surround the first columnar electrode 34 when viewed in a direction orthogonal to the bottom surface 20a of the element body 20.

According to this configuration, when the plurality of second columnar electrodes 35 are connected to the ground potential, the plurality of second columnar electrodes 35 can be caused to function as shields against the first columnar electrodes 34.

In addition, according to the electronic component according to the second embodiment, the outer surface of the element body 20 has a plurality of surfaces including the bottom surface 20a on which the first columnar electrode 34 and the second columnar electrode 35 are provided, the surface excluding the bottom surface 20a among the outer surfaces of the element body 20 and the opposite side from the first columnar electrode 34 with respect to the plurality of second columnar electrodes 35 on the bottom surface 20a are covered with the shield film 90, and the shield film 90 is in contact with the plurality of second columnar electrodes 35.

According to this configuration, when the second columnar electrode 35 is connected to the ground potential, the shield performance of the electronic component 10 is further improved by connecting the second columnar electrode 35 and the shield film 90.

It should be noted that the present disclosure is not limited to the second embodiment, and can be implemented in various other aspects. For example, in the second embodiment, one first columnar electrode 34 is provided, but the present disclosure is not limited thereto. For example, two or more first columnar electrodes 34 may be provided.

In addition, in the second embodiment, the electronic component 10 includes the first columnar electrode 34 and the second columnar electrode 35 having two kinds of diameters, but the present disclosure is not limited thereto. The electronic component 10 may include columnar electrodes having three or more kinds of diameters. For example, the electronic component 10 may include a columnar electrode having a diameter larger than that of the first columnar electrode 34 in addition to the first columnar electrode 34 and the second columnar electrode 35.

In addition, in the first modification of the second embodiment, the number of the first columnar electrodes 34 included in the electronic component 10 is three, but the number of the first columnar electrodes 34 is not limited thereto. For example, at least one first columnar electrode 34 only needs to be provided.

In addition, in the first modification of the second embodiment, the number of the second columnar electrodes 35 included in the electronic component 10 is 16, but the number of the second columnar electrodes 35 is not limited thereto. For example, at least one second columnar electrode 35 only needs to be provided.

The present disclosure has been sufficiently described in connection with the embodiments with reference to the accompanying drawings, but various modifications and corrections are apparent for those skilled in the art. It should be understood that as long as such modifications and corrections do not depart from the scope of the present disclosure by the attached claims, they are included therein.
10 electronic component
11 circuit module
20 element body
20a bottom surface
20b top surface
20c side surface
20d sheet
20e main surface
21 carrier film
22 first hole portion
30 columnar electrode
30a base end portion
30b tip portion
31 via conductor
31a end portion
32 first conductive paste
32a third conductive paste
33 second conductive paste
34 first columnar electrode
35 second columnar electrode
40 internal electrode
50 board
50a mounting surface
50b electrode
60 resin sheet
61 carrier film
62 second hole portion
70 laminate
70a rounded work portion
70b rounded work portion
70c rounded work portion
71 coupled laminate
71a cut line
71b cut line
72 laminate
80 plating
10 81 solder
82 coating portion
90 shield film

What is claimed is:

1. An electronic component comprising:
an element body having an outer surface;
a via conductor penetrating at least a part of the element body in a thickness direction of the element body, the via conductor provided so that one end surface is flush with an outer surface of the element body; and
at least one columnar electrode having a base end portion electrically connected to the one end surface of the via conductor, so as to protrude in the thickness direction from the outer surface of the element body wherein
a length in the thickness direction of the columnar electrode is longer than a maximum width in a cross section orthogonal to the thickness direction of the columnar electrode.

2. The electronic component of claim 1, wherein
the columnar electrode has a tapered portion having an outer shape gradually narrowing from a tip portion on an opposite side from the base end portion toward the base end portion in the thickness direction.

3. The electronic component of claim 1, wherein
the columnar electrode has a tapered portion having an outer shape gradually narrowing from a place closer to the base end portion than to a tip portion on an opposite side from the base end portion to the tip portion in the thickness direction.

4. The electronic component of claim 2, wherein
the tapered portion is provided in a part of the columnar electrode comprising the tip portion of the columnar electrode.

5. The electronic component of claim 1, further comprising:
a covering portion covering an outer circumferential surface around the thickness direction of the columnar electrode.

6. The electronic component of claim 5, wherein
a part of the columnar electrode comprising the tip portion of the columnar electrode is covered with plating, and wherein
the covering portion covers a portion not covered with the plating in the columnar electrode.

7. The electronic component of claim 1, wherein
the at least one columnar electrode comprises a plurality of columnar electrodes on an outer surface of the element body, and wherein,
a size of a cross section orthogonal to the thickness direction of at least one of the plurality of columnar electrodes is different from a size of the cross section of each of the other ones of the plurality of columnar electrodes.

8. The electronic component of claim 1, wherein
the columnar electrode comprises:
at least one first columnar electrode, and
a plurality of second columnar electrodes arranged so as to surround the first columnar electrode as viewed in a direction orthogonal to an outer surface of the element body.

9. The electronic component of claim 8, wherein
an outer surface of the element body has a plurality of surfaces comprising a bottom surface on which the columnar electrode is provided, wherein
a surface excluding the bottom surface among outer surfaces of the element body and an opposite side from the first columnar electrode with respect to the plurality of second columnar electrodes on the bottom surface are covered with a shield film, and wherein
the shield film is in contact with the plurality of second columnar electrodes.

10. The electronic component of claim 1, wherein
the columnar electrode and the via conductor are connected so that an axis of the columnar electrode and an axis of the via conductor are coaxial.

11. A circuit module comprising:
the electronic component according to claim 1; and
a board on which the electronic component is mounted through the columnar electrode.

12. A method for manufacturing an electronic component comprising:
a first filling step of providing at least one first hole portion in at least one sheet not burned out and filling each of the first hole portion with a first conductive paste to form a via conductor;
a second filling step of providing at least one second hole portion in at least one resin sheet and filling each of the second hole portion with a second conductive paste;
a lamination step of laminating the resin sheet on the sheet so that the first hole portion and the second hole portion communicate with each other after the first filling step and the second filling step to form at least one laminate; and
a firing step of firing the laminate to burn out the resin sheet, forming, as an element body, a portion of the not-burned-out sheet, and forming, as a columnar electrode, the second conductive paste filled in the second hole portion of the burned-out resin sheet.

13. The method for manufacturing an electronic component of claim 12, wherein
in the lamination step, the at least one laminate comprises a plurality of laminates, and a coupled laminate in which the plurality of laminates are integrated in a state of being arranged on a same plane is formed, and further comprising
a separation step of dicing the coupled laminate to form the plurality of laminates after the lamination step.

14. The method for manufacturing an electronic component of claim 13, wherein
in the separation step, the coupled laminate is diced into the plurality of laminates so that an outer edge portion of the sheet and an outer edge portion of the resin sheet are flush with each other as viewed in a laminating direction.

15. The method for manufacturing an electronic component of claim 13, wherein
in the separation step, the coupled laminate is diced into the plurality of laminates so that the sheet protrudes outward from the resin sheet as viewed in the laminating direction.

16. The electronic component of claim 3, wherein
the tapered portion is provided in a part of the columnar electrode comprising the tip portion of the columnar electrode.

17. The electronic component of claim 2, further comprising:
a covering portion covering an outer circumferential surface around the thickness direction of the columnar electrode.

18. The electronic component of claim 3, further comprising:
a covering portion covering an outer circumferential surface around the thickness direction of the columnar electrode.

19. The electronic component of claim 4, further comprising:
a covering portion covering an outer circumferential surface around the thickness direction of the columnar electrode.

20. The electronic component of claim 2, wherein
the at least one columnar electrode comprises a plurality of columnar electrodes on an outer surface of the element body, and wherein,
a size of a cross section orthogonal to the thickness direction of at least one of the plurality of columnar electrodes is different from a size of the cross section of each of the other ones of the plurality of columnar electrodes.
